(19) United States
(12) Patent Application Publication
(10) Pub. No.: US 2026/0045446 A1
(43) Pub. Date: Feb. 12, 2026

(54) OUTPUT WINDOW UNIT

(71) Applicant: HAMAMATSU PHOTONICS K.K., Hamamatsu-shi, Shizuoka (JP)

(72) Inventors: Yoshinori HONDA, Hamamatsu-shi (JP); Takeaki HATTORI, Hamamatsu-shi, Shizuoka (JP)

(73) Assignee: HAMAMATSU PHOTONICS K.K., Hamamatsu-shi, Shizuoka (JP)

(21) Appl. No.: 19/101,332

(22) PCT Filed: May 31, 2023
(86) PCT No.: PCT/JP2023/020313

§ 371 Date: Feb. 5, 2025

(30) Foreign Application Priority Data
Sep. 8, 2022 (JP) 2022-142985

(51) Int. Cl. H01J 37/30

(52) U.S. Cl. CPC H01J 37/3007; H01J 2237/303

(57) ABSTRACT

An output window unit includes a window foil that transmits an electron beam toward an outside of a housing; and a support member fixed to the housing and supporting the window foil. The support member includes a mesh portion which faces the window foil and in which a plurality of through-holes through which the electron beam from an electron source passes toward a window foil side are formed, a frame portion having a solid shape and formed integrally with the mesh portion to surround the mesh portion when viewed in a first direction that is a direction in which the window foil and the mesh portion face each other, an outer portion located outside the mesh portion and the frame portion when viewed in the first direction, and formed integrally with the mesh portion and the frame portion, and a recess formed to be recessed along the first direction.

### TECHNICAL FIELD

The present disclosure relates to an output window unit.

### BACKGROUND ART

Patent Literature 1 describes an electron beam transmission unit provided in an electron beam irradiation device. The electron beam transmission unit includes a fixing member, a support member, a window foil, and a pressing member. The fixing member has a substantially rectangular frame shape, and is fixed to a chamber side that accommodates an electron gun. The support member includes a mesh portion through which an electron beam passes, and is fixed to a front surface of the fixing member by brazing or the like. The window foil is disposed on the front surface of the fixing member to cover the support member. The pressing member is fixed to the fixing member by bolts in a state where the pressing member presses a peripheral edge portion of the window foil against the fixing member.

### CITATION LIST

### Patent Literature

Patent Literature 1: Japanese Patent No. 6343154

### SUMMARY OF INVENTION

### Technical Problem

By the way, in an electron beam output window structure such as the above-described electron beam transmission unit, the mesh portion and the window foil absorb a part of the electron beam, thereby causing the mesh portion and the window foil to generate heat. When the window foil becomes hot, oxidation of the window foil is accelerated, thereby resulting in a reduction in the strength of the window foil, which is a risk. Therefore, as a structure for cooling the window foil, for example, it is considered that a flow path through which a refrigerant flows is provided in the fixing member. However, in this case, contact thermal resistance between the support member and the fixing member can be a factor that reduces heat dissipation of the window foil to the fixing member (refrigerant flow path) via the support member.

Meanwhile, when the mesh portion of the support member is thick, the transmittance of an obliquely incident electron beam decreases compared to when the mesh portion is thin. Namely, electrons are likely to collide with the mesh portion, and the mesh portion is likely to generate heat. Therefore, in this case, the window foil is also likely to become hot. However, when the mesh portion is made thin to improve the transmittance of an obliquely incident electron beam, the strength of the support member including the mesh portion decreases. As described above, in the above-described technical field, there is a demand for suppressing a reduction in the strength of the window foil, the mesh portion, or the like and improving reliability.

An object of the present disclosure is to provide an output window unit capable of improving reliability.

### Solution to Problem

An output window unit according to the present disclosure is [1] “an output window unit provided in an electron beam irradiation device including an electron source and a housing accommodating the electron source, and configured to output an electron beam from the electron source to an outside of the housing, including: a window foil configured to transmit the electron beam toward the outside of the housing; and a support member fixed to the housing and configured to support the window foil. The support member includes a mesh portion facing the window foil and in which a plurality of through-holes through which the electron beam from the electron source passes toward a window foil side are formed, a frame portion having a solid shape and formed integrally with the mesh portion to surround the mesh portion when viewed in a first direction that is a direction in which the window foil and the mesh portion face each other, an outer portion located outside the mesh portion and the frame portion when viewed in the first direction, and formed integrally with the mesh portion and the frame portion, and a recess formed to be recessed along the first direction. The outer portion includes a fixing portion used to fix the support member to the housing, and forms an edge portion of the recess. The mesh portion and the frame portion form a bottom surface portion of the recess, so that a thickness of the mesh portion and the frame portion in the first direction is thinner than a thickness of at least a portion forming the edge portion in the outer portion.”

In the output window unit according to the above [1], the window foil that transmits the electron beam toward the outside of the housing is supported by the support member. In the support member, the outer portion including the fixing portion used to fix the support member to the housing and the mesh portion that faces the window foil and that transmits the electron beam to the window foil side are integrally formed. Therefore, contact thermal resistance does not exist between the mesh portion and the outer portion including the fixing portion, and a reduction in the heat dissipation of the window foil to the fixing portion via the mesh portion is suppressed.

Particularly, the recess is formed in the support member, and the mesh portion forms a part of the bottom surface portion of the recess and the outer portion including the fixing portion forms the edge portion of the recess, so that the mesh portion is made relatively thin and at least a part of the outer portion is made relatively thick. Therefore, the transmittance of the mesh portion for an obliquely incident electron beam is improved, the heat capacity of the fixing portion is ensured, and heat generation of the mesh portion is suppressed. Therefore, an increase in the temperature of the window foil is suppressed, and a reduction in the strength of the window foil is suppressed.

Further, in the support member, the frame portion having a solid shape is provided to surround the mesh portion, and the frame portion and the mesh portion form a bottom surface of the recess. Namely, an outer edge of the bottom surface portion of the recess is not the mesh portion but the frame portion having a solid shape. Accordingly, even when the mesh portion is configured to be relatively thin, strength is ensured. As described above, in the output window unit according to the above [1], a reduction in the strength of the window foil, the mesh portion, and the like is suppressed, and reliability is improved.

The output window unit according to the present disclosure may be [2] “the output window unit according to the above [1] in which a corner portion forming a connecting portion between the bottom surface portion and the edge portion of the recess is chamfered.” In this case, a reduction in the strength of the bottom surface portion of the recess is further suppressed.

The output window unit according to the present disclosure may be [3] “the output window unit according to the above [1] or {2] in which a first flow path formed inside the fixing portion and configured to flow a first refrigerant.” In this case, the window foil and the mesh portion can be cooled by the refrigerant flowing through the flow path inside the fixing portion.

The output window unit according to the present disclosure may be [4] “the output window unit according to any one of the above [1] to [3], further including: a pressing member configured to press the window foil against the support member; and a cooling portion configured to spray a second refrigerant, which is a gas, onto the window foil. An opening portion configured to expose at least a facing portion is formed in the pressing member, the facing portion being a part of the window foil and facing the mesh portion when viewed in the first direction. The cooling portion sprays the second refrigerant onto the facing portion of the window foil through the opening portion of the pressing member.” In this case, the window foil can be directly cooled by spraying the gaseous refrigerant onto the window foil.

The output window unit according to the present disclosure may be [5] “the output window unit according to the above [4] in which the cooling portion includes a second flow path formed inside the pressing member and configured to flow the second refrigerant, and a communication hole allowing communication between the second flow path and an inside of the opening portion, and sprays the second refrigerant, which has flowed through the second flow path, onto the facing portion by leading out the second refrigerant into the inside of the opening portion through the communication hole.” In this case, the flow path and a lead out portion (communication hole) for the refrigerant can be formed in the pressing member that presses the window foil against the support member.

The output window unit according to the present disclosure may be [6] “the output window unit according to any one of the above [1] to [5] in which the recess is open toward a housing side, and the window foil is disposed on a front surface of the support member opposite to an opening of the recess.” In this case, access to the window foil is facilitated.

The output window unit of the present disclosure may be [7] “the output window unit according to any one of the above [1] to [5] in which the recess is open toward a side opposite to the housing, and the window foil is disposed inside the recess.” In this case, since the window foil is disposed inside the recess, inadvertent contact with the window foil is suppressed.

### Advantageous Effects of Invention

According to the present disclosure, it is possible to provide the output window unit capable of improving reliability.

### BRIEF DESCRIPTION OF DRAWINGS

FIG. 1 is a perspective view of an electron beam irradiation device according to the present embodiment.

FIG. 2 is a partial cross-sectional view illustrating an internal structure of the electron beam irradiation device illustrated in FIG. 1.

FIG. 3 is a cross-sectional view taken along line III-III in FIG. 1.

FIG. 4 is a perspective view of an output window unit illustrated in FIGS. 1 to 3.

FIG. 5 is a bottom view of the output window unit illustrated in FIG. 4.

FIG. 6 is a schematic cross-sectional view taken along line VI-VI in FIG. 5.

FIG. 7 is cross-sectional views illustrating support members according to modification examples.

FIG. 8 is a perspective view illustrating an output window unit according to a modification example.

FIG. 9 is a schematic cross-sectional view taken along line IX-IX in FIG. 8.

FIG. 10 is a perspective view illustrating an attachment/detachment jig for the output window unit.

FIG. 11 is a side view of the attachment/detachment jig illustrated in FIG. 10.

FIG. 12 is a perspective view for describing a procedure for attaching the output window unit to a vacuum container using the attachment/detachment jig illustrated in FIGS. 10 and 11.

FIG. 13 is a perspective view schematically illustrating a cooling portion of the electron beam irradiation device.

FIG. 14 is a schematic view illustrating a structure for adjusting the air pressure inside the vacuum container.

FIG. 15 is a schematic view illustrating a configuration of a supply unit illustrated in FIG. 14.

### DESCRIPTION OF EMBODIMENTS

Hereinafter, one embodiment of the present disclosure will be

described with reference to the drawings. In each drawing, the same or corresponding elements are denoted by the same reference signs, and duplicate descriptions may be omitted.

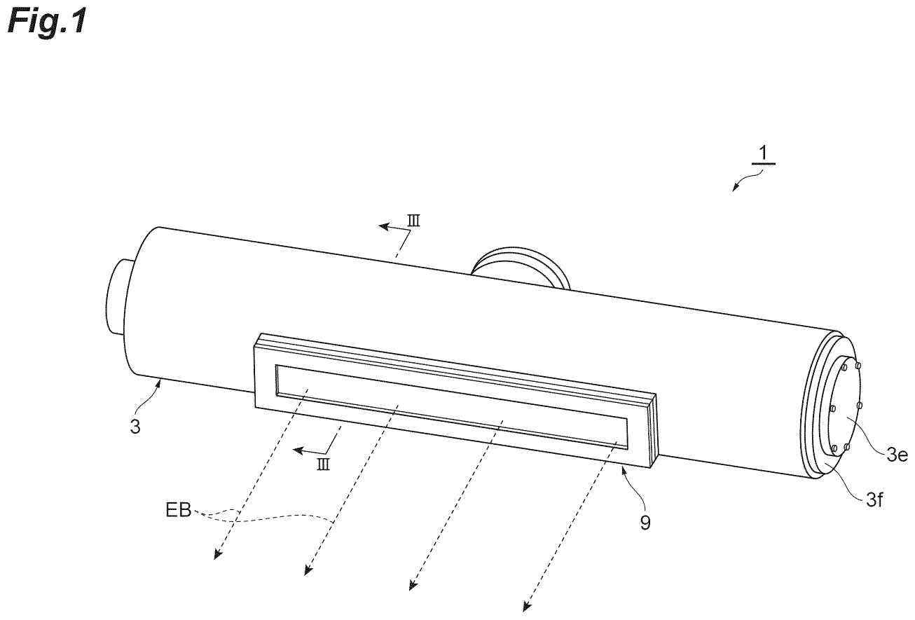

FIG. 1 is a perspective view of an electron beam irradiation device according to the present embodiment. For example, an electron beam irradiation device 1 illustrated in FIG. 1 is used to perform the curing, sterilization, surface modification, or the like of an object of irradiation by irradiating the object of irradiation with an electron beam EB. Incidentally, hereinafter, an electron beam emission side (output window unit 9 side) that is irradiated with the electron beam EB by the electron beam irradiation device 1 will be described as a “front side”.

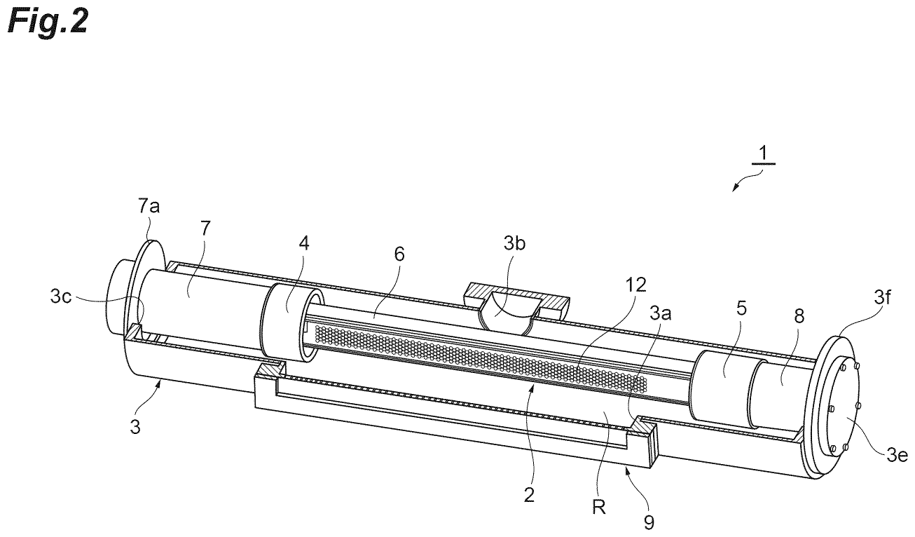

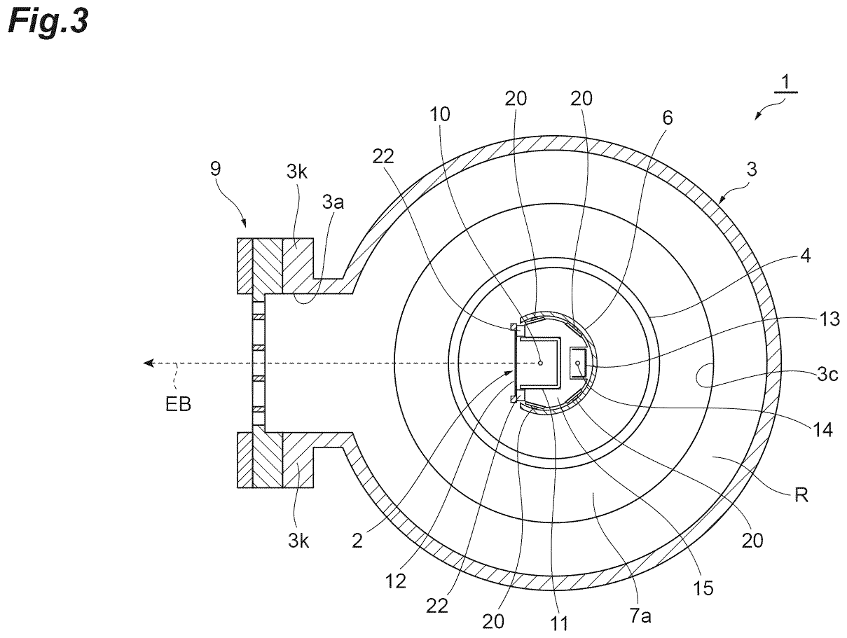

FIG. 2 is a partial cross-sectional view illustrating an internal structure of the electron beam irradiation device illustrated in FIG. 1. FIG. 3 is a cross-sectional view taken along line III-III in FIG. 1. As illustrated in FIGS. 1 to 3, the electron beam irradiation device 1 includes a filament unit (electron emitting unit) 2, a vacuum container (housing) 3, a cathode holding member 4, a cathode holding member 5, a rail unit (unit accommodating unit) 6, a high-voltage introduction insulating member (power feeding unit) 7, and an insulating support member 8. The filament unit 2 is an electron beam generation unit (namely, an electron source) that generates the electron beam EB. In addition, the filament unit 2 is an elongated unit.

The vacuum container 3 is formed from a conductive material such as metal. The vacuum container 3 has a substantially cylindrical shape. The vacuum container 3 forms a vacuum space R having a substantially columnar shape therein. The filament unit 2 is accommodated in the vacuum container 3, and is disposed inside the vacuum container 3 along an axial direction (longitudinal direction) of the vacuum space R having a substantially columnar shape. An opening portion 3a that allows communication between the vacuum space R and an external space is provided in the vacuum container 3 at a position in front of the filament unit 2.

The vacuum container 3 is provided with the output window unit 9 for outputting electrons, which are emitted from the filament unit 2, to the outside of the vacuum container 3. The output window unit 9 is fixed to the opening portion 3a to vacuum-seal the opening portion 3a. Specifically, the output window unit 9 is fixed to a flange portion 3k that defines the opening portion 3a of the vacuum container 3.

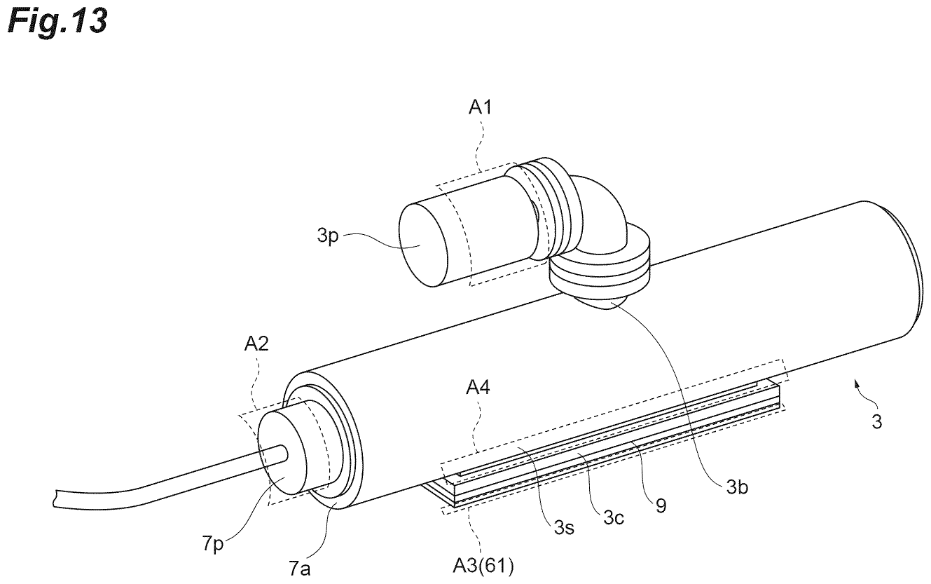

An exhaust port 3b for discharging air from inside the vacuum container 3 is provided in the vacuum container 3 at a position behind the filament unit 2. A vacuum pump 3p is connected to the exhaust port 3b (refer to FIG. 13), and air inside the vacuum container 3 is discharged by the vacuum pump 3p. Accordingly, the inside of the vacuum container 3 becomes the vacuum space R.

An opening portion 3c at an end portion on the other side of the vacuum container 3 having a substantially cylindrical shape is closed by a flange portion 7a of the high-voltage introduction insulating member 7. A housing end plate 3f is provided at an end portion on one side of the vacuum container 3. The housing end plate 3f is provided with an insertion port (not illustrated) communicating with an inner space and an outer space of the vacuum container 3. The insertion port is sized to allow the filament unit 2 to be introduced therethrough. The insertion port is closed by a lid portion 3e provided to be openable and closable (here, to be detachable) with respect to the housing end plate 3f.

A pair of the cathode holding members 4 and 5 forming a cathode potential are disposed inside the vacuum container 3. Between the cathode holding member 4 on the other side and the cathode holding member 5 on the one side, a cathode potential is formed, and the rail unit 6 also serving as a surrounding electrode that surrounds the filament unit 2 is provided. The rail unit 6 is a conductive and elongated member having a substantially C-shaped cross section. The rail unit 6 is disposed such that an opening having a substantially C-shaped cross section faces the front side (output window unit 9 side). The rail unit 6 holds the filament unit 2 in an inner portion (internal space).

In other words, the rail unit 6 has an elongated tubular shape capable of accommodating the filament unit 2. In addition, an opening (electron emission opening) is formed in a portion of an outer peripheral surface of the rail unit 6, the portion facing the output window unit 9. Both end portions of the rail unit 6 are fixed to the vacuum container 3 by the cathode holding member 4 and the high-voltage introduction insulating member 7 and by the cathode holding member 5 and the insulating support member 8, respectively.

An insertion port 3d of the housing end plate 3f faces one end portion (an end portion fixed to the cathode holding member 5) of the rail unit 6. In a state where the lid portion 3e of the vacuum container 3 is removed (opened), the filament unit 2 is inserted into the inside (inner space) of the rail unit 6 from the one end portion of the rail unit 6 through the insertion port 3d of the housing end plate 3f and an insertion hole provided in each of the cathode holding member 5 and the insulating support member 8, and is held by the rail unit 6. In such a manner, the filament unit 2 can be inserted into and removed from the rail unit 6 from the one end portion of the rail unit 6 (is detachably inserted).

The high-voltage introduction insulating member 7 feeds power to the filament unit 2. The high-voltage introduction insulating member 7 is provided at the end portion on an opening portion 3c side of the other side of the vacuum container 3. An end portion on the other side of the high-voltage introduction insulating member 7 protrudes to the outside of the vacuum container 3 through the opening portion 3c. The high-voltage introduction insulating member 7 includes the flange portion 7a projecting outward in a radial direction, and seals the opening portion 3c of the vacuum container 3. The high-voltage introduction insulating member 7 is formed from an insulating material (for example, insulating resin such as epoxy resin, ceramic, or the like). The cathode holding member 4 holds an end portion on the one side of the high-voltage introduction insulating member 7 in a state where the cathode holding member 4 is electrically insulated from the vacuum container 3 that is at ground potential.

In addition, the high-voltage introduction insulating member 7 is a high-voltage resistant connector for receiving a high voltage supply from a power supply device external to the electron beam irradiation device 1. A high-voltage supply plug 7p from the power supply device (not illustrated) is inserted into the high-voltage introduction insulating member 7 (refer to FIG. 13). An internal wiring for supplying a high voltage supplied from the outside to the filament unit 2 and the like is provided inside the high-voltage introduction insulating member 7.

The internal wiring is covered with an insulating material constituting the high-voltage introduction insulating member 7, and insulation from the vacuum container 3 is ensured. The end portion on the one side of the high-voltage introduction insulating member 7, the end portion being disposed inside the vacuum container 3 (end portion that supports the cathode holding member 4), faces an end portion on the other side of the rail unit 6 (an end portion fixed to the cathode holding member 4).

The insulating support member 8 is provided at the end portion of the vacuum container 3 on the one side where the housing end plate 3f is provided (end portion on a lid portion 3e side). The insulating support member 8 is formed from an insulating material (for example, insulating resin such as epoxy resin, ceramic, or the like). The insulating support member 8 is supported by the housing end plate 3f. The cathode holding member 5 is supported by the insulating support member 8 in a state where the cathode holding member 5 is electrically insulated from the vacuum container 3.

The filament unit 2 is configured as a single unit so as to be attachable to and detachable from the rail unit 6. The filament unit 2 includes a filament 10, a main frame 11, a grid electrode 12, a subframe 13, and a power feeding line 14.

The main frame 11 is an elongated member having a substantially U-shaped cross section. The main frame 11 is disposed such that an opening having a substantially U-shaped cross section faces the front side (output window unit 9 side). The filament 10 is an electron emitting unit that emits electrons that become the electron beam EB when heated by energization. The filament 10 is an elongated wire-shaped member. The filament 10 is formed from a high-melting point metal material, for example, a material containing tungsten as a main component, or the like.

The subframe 13 is an elongated member having a substantially U-shaped cross section. The subframe 13 is disposed parallel to the main frame 11. The power feeding line 14 passes through the inside (inner space) of the subframe 13, and the subframe 13 has a protective function for the power feeding line 14. The main frame 11 and the subframe 13 are connected to each other by a plurality of guide members 15.

A plurality of positioning portions 20 are provided on outer surfaces of the guide members 15. The positioning portions 20 come into slidable contact with an inner surface of the rail unit 6, and perform the positioning of the filament unit 2 with respect to the rail unit 6. A plurality of the positioning portions 20 are provided along an extending direction of the filament 10.

The grid electrode 12 is disposed in front of the filament 10, and is supported by the guide members 15 via insulating members 22. A plurality of holes are formed in the grid electrode 12. The grid electrode 12 is electrically connected to a grid electrode terminal via a wiring (not illustrated).

In a state where the filament unit 2 is inserted to a complete insertion position of the rail unit 6 and the filament 10 is heated by energization, when a high negative voltage of minus several tens of kV to minus several hundreds of kV is applied to the filament 10, the filament 10 emits electrons. A predetermined voltage is applied to the grid electrode 12. For example, a voltage that is shifted to the positive side by approximately 100 V to 150 V from the negative voltage applied to the filament 10 may be applied to the grid electrode 12. The grid electrode 12 forms an electric field for extracting electrons and suppressing diffusion. Accordingly, the electrons emitted from the filament 10 are emitted from the holes provided in the grid electrode 12 toward the front side as the electron beam EB.

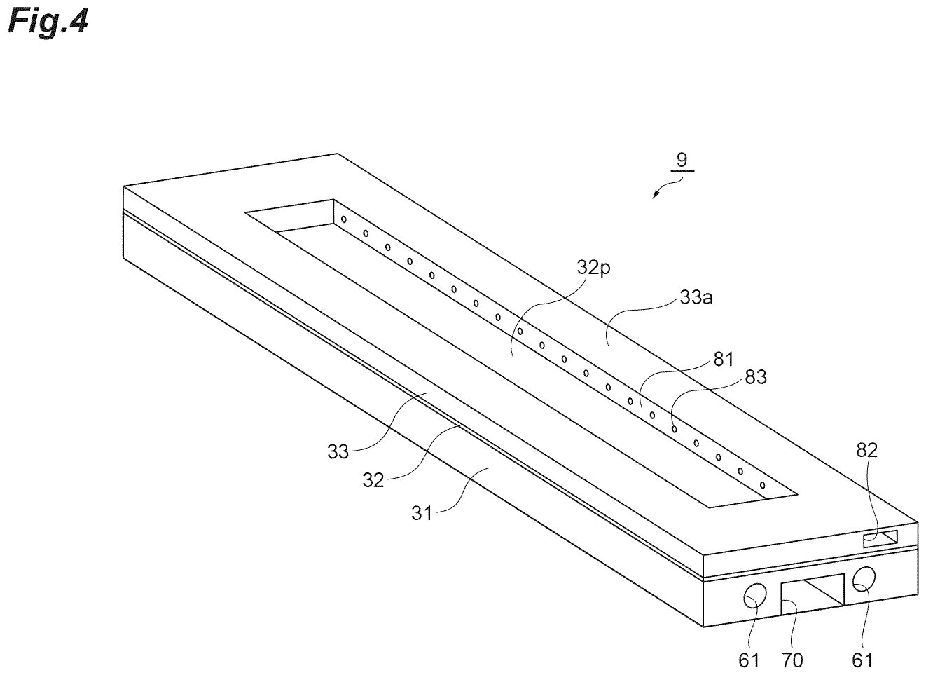

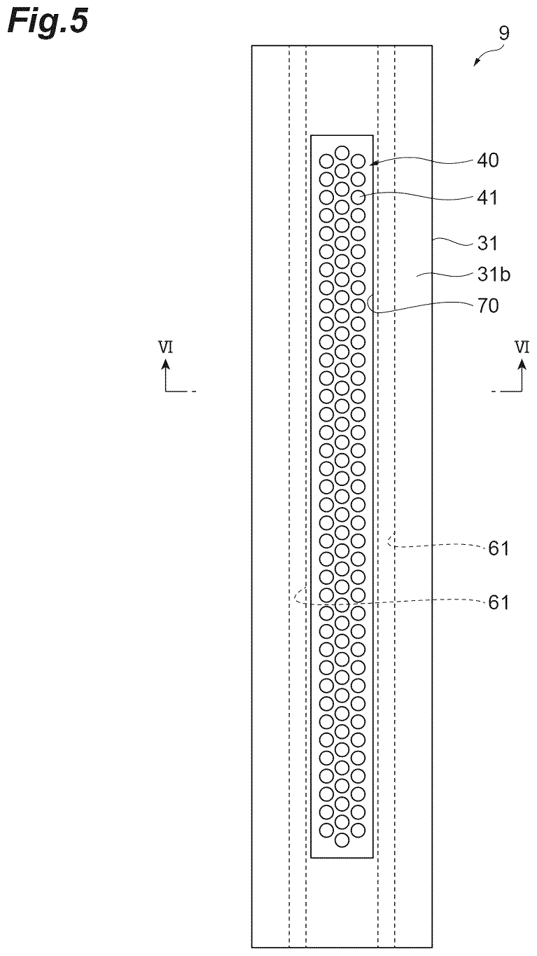

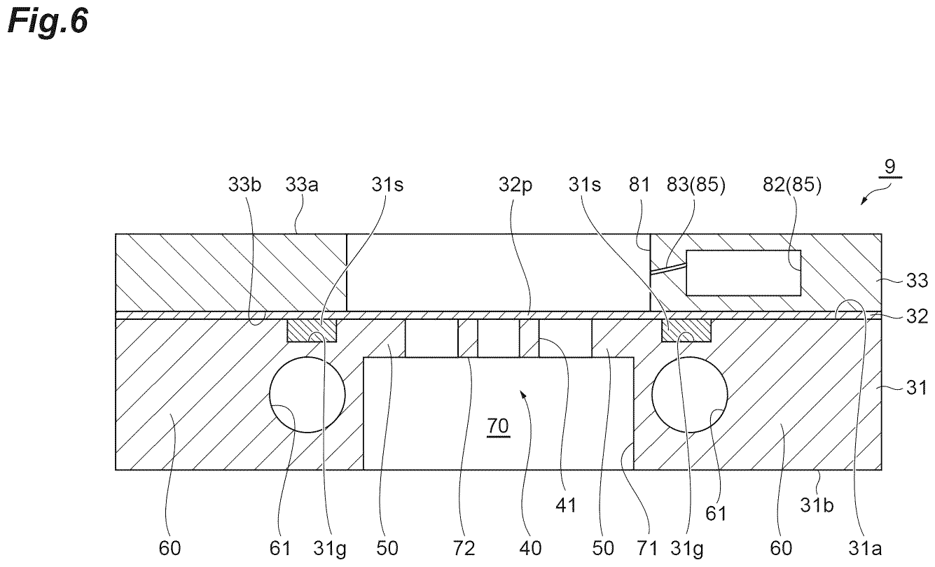

FIG. 4 is a perspective view of the output window unit illustrated in FIGS. 1 to 3. FIG. 5 is a bottom view of the output window unit illustrated in FIG. 4. FIG. 6 is a schematic cross-sectional view taken along line VI-VI in FIG. 5. As illustrated in FIGS. 4 to 6, the output window unit 9 includes a support member 31, a window foil 32, and a pressing member 33.

The support member 31 supports the window foil 32. The support member 31 includes a front surface 31a and a back surface 31b opposite to the front surface 31a. The support member 31 is disposed such that the back surface 31b comes into contact with the flange portion 3k of the vacuum container 3. The output window unit 9 is fixed to the vacuum container 3 via the support member 31. The support member 31 is integrally formed from, for example, a metal material having good thermal conductivity, such as a material containing copper. The window foil 32 is disposed on the front surface 31a of the support member 31, the front surface 31a facing away from the vacuum container 3, and is supported by the support member 31. The window foil 32 is in contact with, for example, the support member 31 at the front surface 31a, and is thermally connected to the support member 31. The window foil 32 transmits the electron beam EB toward the outside of the vacuum container 3. The material of the window foil 32 is a material having excellent property of transmitting the electron beam EB (for example, beryllium, titanium, aluminum, or the like).

The pressing member 33 presses the window foil 32 against the support member 31. The pressing member 33 includes a front surface 33a and a back surface 33b opposite to the front surface 33a. The pressing member 33 is disposed in contact with the window foil 32 such that the back surface 33b faces the side of the window foil 32 and the support member 31. The pressing member 33 is made of, for example, a metal material having good thermal conductivity, such as a material containing copper. The support member 31, the window foil 32, and the pressing member 33 have substantially the same elongated rectangular shape when viewed in a stacking direction (first direction) thereof.

Here, the support member 31 includes a mesh portion 40, a frame portion 50, a fixing portion (outer portion) 60, and a recess 70. The mesh portion 40, the frame portion 50, and the fixing portion 60 are integrally formed. The mesh portion 40 faces the window foil 32 (here, the frame portion 50 and the fixing portion 60 also face the window foil 32). A plurality of through-holes 41 through which the electron beam EB passes toward a window foil 32 side are formed in the mesh portion 40.

The through-holes 41 are provided to penetrate through the support member 31 along the first direction (here, a direction intersecting the front surface 31a and the back surface 31b) that is a direction in which the window foil 32 and the mesh portion 40 face each other, and are disposed in a plane intersecting the first direction. In other words, a portion of the support member 31 in which the through-holes 41 are provided is the mesh portion 40. The outer shape of the mesh portion 40 when viewed in the first direction is an elongated rectangular shape of which a longitudinal direction is aligned with a longitudinal direction of the support member 31.

The frame portion 50 is a rectangular frame-shaped portion of which a longitudinal direction is aligned with the longitudinal direction of the support member 31 when viewed in the first direction, and is provided to surround the entirety of the mesh portion 40. The frame portion 50 is a solid region in which the through-holes 41 and the like are not provided.

As will be described later, the fixing portion 60 is used to fix the support member 31 to the vacuum container 3. The fixing portion 60 is a rectangular frame-shaped portion of which a longitudinal direction is aligned with the longitudinal direction of the support member 31 when viewed in the first direction, and is located outside the mesh portion 40 and the frame portion 50. Here, the fixing portion 60 is formed in a rectangular frame shape when viewed in the first direction, and is provided to surround the entirety of the frame portion 50. Here, when viewed in the first direction, the outer shape of the fixing portion 60 defines the outer shape of the support member 31.

A flow path (first flow path) 61 through which a refrigerant (first refrigerant) that is, for example, a liquid flows is formed in the fixing portion 60. Here, the flow paths 61 are formed in a pair to sandwich the mesh portion 40 and the frame portion 50 in a transverse direction of the fixing portion 60 and the support member 31 when viewed in the first direction, and extend in the longitudinal direction of the fixing portion 60 and the support member 31. The pair of flow paths 61 are each open on both end surfaces of the fixing portion 60 and the support member 31 in the longitudinal direction, and the openings provide an introduction port and a discharge port for the refrigerant.

The recess 70 is formed in the support member 31 to be recessed in the first direction. The recess 70 is formed in an elongated rectangular shape of which a longitudinal direction is aligned with the longitudinal direction of the support member 31 when viewed in the first direction. Here, the recess 70 is provided on the back surface 31b of the support member 31, and is open toward a vacuum container 3 side. Accordingly, the recess 70 exposes the mesh portion 40 and the frame portion 50 to the vacuum container 3 side at a bottom surface portion 72 of the recess 70.

In other words, in the support member 31, the mesh portion 40 and the frame portion 50 form the bottom surface portion 72 of the recess 70. In addition, in the support member 31, the fixing portion 60 forms an edge portion 71 of the recess 70. Accordingly, a thickness of the mesh portion 40 and the frame portion 50 in the first direction is thinner than a thickness of the fixing portion 60 by the depth of the recess 70. In the support member 31, a connecting portion between the bottom surface portion 72 of the recess 70 and the edge portion 71 serves as the frame portion 50. In addition, the window foil 32 is disposed on the front surface 31a of the support member 31 opposite to the opening of the recess 70.

In the output window unit 9 described above, the pressing member 33 is fastened by fastening members (not illustrated) such as bolts inserted into the fixing portion 60 in a state where the pressing member 33 is disposed in contact with the window foil 32, so that the pressing member 33 is fixed to the support member 31 while pressing the window foil 32 toward the support member 31 side. A groove 31g having a frame shape is formed on the front surface 31a of the support member 31 to surround the mesh portion 40 and the frame portion 50, and a sealing member 31s (for example, an O-ring) made of an elastic body is disposed in the groove 31g. The majority of the sealing member 31s (for example, a portion along the longitudinal direction of the support member 31) is disposed to overlap the flow paths 61 when viewed in the first direction, and can be cooled by the refrigerant flowing through the flow paths 61. Therefore, the influence of heat from the window foil 32 or the mesh portion 40 on the sealing member 31s is suppressed, and a reduction in hermetic sealing performance caused by deterioration of the sealing member 31s due to heat is suppressed. Further, since the sealing member 31s includes a portion overlapping a cooling portion 85 to be described later when viewed in the first direction, the influence of heat is further suppressed.

When the pressing member 33 is fixed to the support member 31, the pressing member 33 presses the sealing member toward the support member 31 side via the window foil 32, so that a gap between the window foil 32 and the support member 31 is hermetically sealed. Furthermore, the output window unit 9 is fixed to the vacuum container 3, for example, by inserting fastening members (not illustrated) such as bolts into through-holes penetrating through the pressing member 33 and the support member 31 (fixing portion 60), and fastening the fastening members to the flange portion 3k of the vacuum container 3. Accordingly, the opening portion 3a of the vacuum container 3 is hermetically sealed.

Incidentally, an opening portion 81 that is a through-hole extending from the back surface 33b to the front surface 33a is formed in the pressing member 33. The opening portion 81 exposes at least a facing portion 32p of the window foil 32, which faces (comes into contact with) the mesh portion 40, to a side opposite to the vacuum container 3. Accordingly, in the output window unit 9, a passage for the electron beam EB is ensured by the recess 70, the mesh portion 40 (through-holes 41), the window foil 32, and the opening portion 81.

In addition, a flow path (second flow path) 82 through which a refrigerant (second refrigerant, for example, an inert gas such as nitrogen) that is a gas is formed in the pressing member 33. The flow path 82 is provided on one side of the opening portion 81 in the transverse direction of the pressing member 33 when viewed in the first direction, and extends along the longitudinal direction of the pressing member 33. The flow path 82 is open, for example, on one end surface of the pressing member 33 in the longitudinal direction, and the opening provides an introduction port for the refrigerant.

Further, a plurality of communication holes 83 that allow communication between the flow path 82 and the inside of the opening portion 81 are provided in the pressing member 33. The plurality of communication holes 83 are arranged spaced apart from each other along the longitudinal direction of the opening portion 81, and are disposed in a distributed manner across substantially the entirety of the opening portion 81 in the longitudinal direction. The communication holes 83 are inclined to approach the back surface 33b as the communication holes 83 extend from the flow path 82 toward the opening portion 81. Accordingly, the refrigerant introduced into the inside of the opening portion 81 from the flow path 82 through the communication holes 83 is ejected toward the window foil 32 on a back surface 33b side.

In such a manner, the output window unit 9 further includes the cooling portion 85 for spraying the refrigerant onto the window foil 32. The cooling portion 85 sprays the refrigerant onto at least the facing portion 32p of the window foil 32 through the opening portion 81 of the pressing member 33. Particularly, the cooling portion 85 sprays the refrigerant onto at least the facing portion 32p by leading out the refrigerant, which has flowed through the flow path 82, into the inside of the opening portion 81 through each of the communication holes 83.

As described above, in the output window unit 9, two cooling mechanisms, namely, a cooling portion including the flow path 61 disposed on the vacuum container 3 side of the window foil 32, and the cooling portion 85 disposed on the side of the window foil 32 opposite to the vacuum container 3 are configured. In the illustrated example, when viewed in the first direction, regions of the support member 31 in which the flow paths 61 are provided is located outside a region of the window foil 32 onto which the refrigerant is sprayed by the cooling portion 85. Therefore, the window foil 32 and the mesh portion 40 can be cooled from outside the window foil 32 and the mesh portion 40 by the flow paths 61, and can be cooled from inside the window foil 32 and the mesh portion 40 by the cooling portion 85.

As described above, in the output window unit 9 according to the present embodiment, the window foil 32 that transmits the electron beam EB toward the outside of the vacuum container 3 is supported by the support member 31. In the support member 31, the fixing portion 60 used to fix the support member 31 to the vacuum container 3 and the mesh portion 40 that faces the window foil 32 and that transmits the electron beam EB toward the window foil 32 side are integrally formed. Therefore, contact thermal resistance does not exist between the mesh portion 40 and the fixing portion 60, and a reduction in the heat dissipation of the window foil 32 to the fixing portion 60 via the mesh portion 40 is suppressed.

Particularly, the recess 70 is formed in the support member 31, and the mesh portion 40 forms a part of the bottom surface portion 72 of the recess 70 and the fixing portion 60 forms the edge portion 71 of the recess 70, so that the mesh portion 40 is made relatively thin and the fixing portion 60 is made relatively thick. Therefore, the transmittance of the mesh portion 40 for an obliquely incident electron beam is improved, the heat capacity of the fixing portion 60 is ensured, the heat dissipation efficiency of the mesh portion 40 is improved, and heat generation is suppressed. Therefore, an increase in the temperature of the window foil 32 is suppressed, and a reduction in the strength of the window foil 32 is suppressed.

Further, in the support member 31, the frame portion 50 having a solid shape is provided to surround the mesh portion 40, and the frame portion 50 and the mesh portion 40 form the bottom surface portion 72 of the recess 70. Namely, an outer edge of the bottom surface portion 72 of the recess 70 is not the mesh portion 40 but the frame portion 50 having a solid shape. Accordingly, even when the mesh portion 40 is configured to be relatively thin, strength is ensured. As described above, in the output window unit 9, a reduction in the strength of the window foil 32, the mesh portion 40, and the like is suppressed, and reliability is improved.

In addition, in the output window unit 9 according to the present embodiment, the flow paths 61 through which a refrigerant flows are formed inside the fixing portion 60. Therefore, the window foil 32 and the mesh portion 40 can be cooled by the refrigerant flowing through the flow paths 61 inside the fixing portion 60.

In addition, the output window unit 9 according to the present embodiment further includes the pressing member 33 that presses the window foil 32 against the support member 31, and the cooling portion 85 for spraying a refrigerant, which is a gas, onto the window foil 32. The opening portion 81 that exposes at least the facing portion 32p of the window foil 32, the facing portion 32p facing the mesh portion 40 when viewed in the first direction, is formed in the pressing member 33, and the cooling portion 85 sprays the refrigerant onto the facing portion 32p of the window foil 32 through the opening portion 81. Therefore, the window foil 32 can be directly cooled by spraying the gaseous refrigerant onto the window foil 32.

In addition, in the output window unit 9 according to the present embodiment, the cooling portion 85 includes the flow path 82 formed inside the pressing member 33, and the communication holes 83 that allow communication between the flow path 82 and the inside of the opening portion 81. The refrigerant that has flowed through the flow path 82 is led out into the inside of the opening portion 81 through the communication holes 83, so that the refrigerant is sprayed onto the facing portion 32p. Therefore, the flow path 82 and lead out portions (communication holes 83) for the refrigerant can be formed in the pressing member 33 that presses the window foil 32 against the support member 31, and there is no need to form the cooling portion 85 using a separate member.

Further, in the output window unit 9 according to the present embodiment, the recess 70 is open toward the vacuum container 3 side, and the window foil 32 is disposed on the front surface 31a of the support member 31 opposite to the opening of the recess 70. Therefore, access to the window foil 32 is facilitated. In addition, even when the thickness of the support member 31 is increased to improve heat dissipation, the distance between the window foil 32 and an object of irradiation does not change, so that cooling performance can be improved while maintaining a predetermined electron beam irradiation efficiency.

The above embodiment has described one aspect of the output window unit. Therefore, the output window unit 9 described above can be optionally modified.

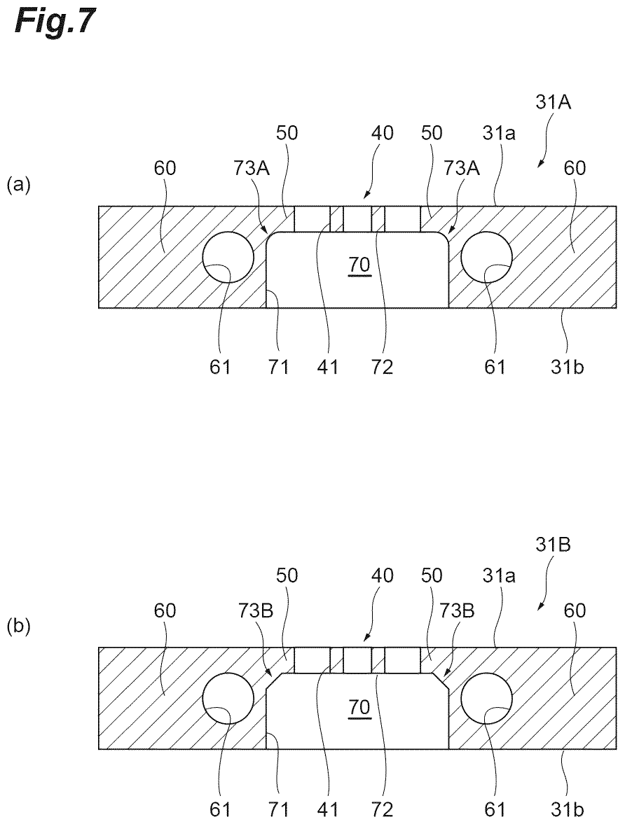

FIG. 7 is cross-sectional views illustrating support members according to modification examples. (a) in FIG. 7 is a cross-sectional view illustrating a support member according to a first modification example, and (b) in FIG. 7 is a cross-sectional view illustrating a support member according to a second modification example. As illustrated in FIG. 7, the output window unit 9 can include a support member 31A or a support member 31B instead of the support member 31. In the support members 31A and 31B, corner portions 73A and 73B forming the connecting portion between the bottom surface portion 72 and the edge portion 71 of the recess 70 are chamfered.

In the support member 31A, the corner portion 73A is chamfered by a curved surface (here, a partial cylindrical surface), and in the support member 31B, the corner portion 73B is chamfered by a flat surface. In such a manner, the aspect of chamfering is optional. The strength of the bottom surface portion 72 is improved by chamfering the corner portions 73A and 73B of the recess 70 in such a manner.

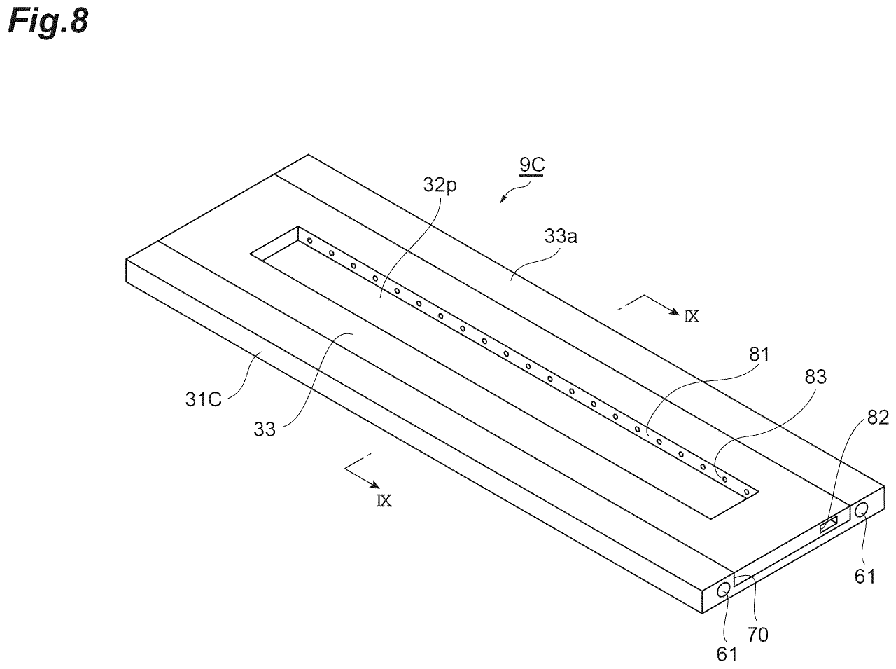

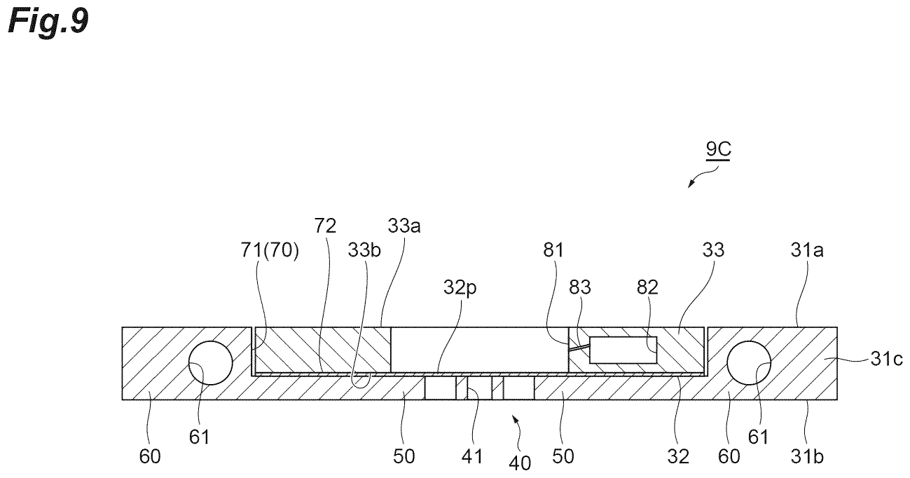

FIG. 8 is a perspective view illustrating an output window unit according to a modification example, and FIG. 9 is a schematic cross-sectional view taken along line IX-IX in FIG. 8. An output window unit 9C illustrated in FIGS. 8 and 9 differs from the output window unit 9 in that a support member 31C is provided instead of the support member 31. The support member 31C differs from the support member 31 in the direction in which the recess 70 are formed.

More specifically, in the support member 31C, the recess 70 is provided on the front surface 31a, and is open toward a side opposite to the vacuum container 3. Furthermore, in the output window unit 9C, the window foil 32 is disposed inside the recess 70 (on the bottom surface portion 72). In addition, in the output window unit 9C, at least a part (here, the entirety) of the pressing member 33 is disposed inside the recess 70. In the illustrated example, a thickness of the pressing member 33 in the first direction is substantially the same as a depth of the recess 70 in the first direction, and the front surface 31a of the support member 31 and the front surface 33a of the pressing member 33 are substantially flush with each other. According to the output window unit 9C, since the window foil 32 is disposed inside the recess 70, inadvertent contact with the window foil 32 is suppressed. In addition, in the output window unit 9C, by disposing the pressing member 33 inside the recess 70, the overall thickness is reduced, and the positioning of the support member 31C and the pressing member 33 is facilitated, so that the attachment of the output window unit 9C to the vacuum container 3 is facilitated.

Incidentally, in the support members 31 to 31C described above, for example, any structure such as a groove or a step that contributes to fixing the support members 31 to 31C may be formed between the fixing portion 60 and the recess 70. Namely, it may be that the support members 31 to 31C include an outer portion located outside the mesh portion 40 and the frame portion 50 when viewed in the first direction and formed integrally with the mesh portion 40 and the frame portion 50 and the outer portion includes the fixing portion 60 used to fix the support members 31 to 31C. In this case, it may be that the outer portion forms the edge portion 71 of the recess 70, and it may be that the thickness of the mesh portion 40 and the frame portion 50 in the first direction is thinner than at least a portion of the outer portion, the portion forming the edge portion 71.

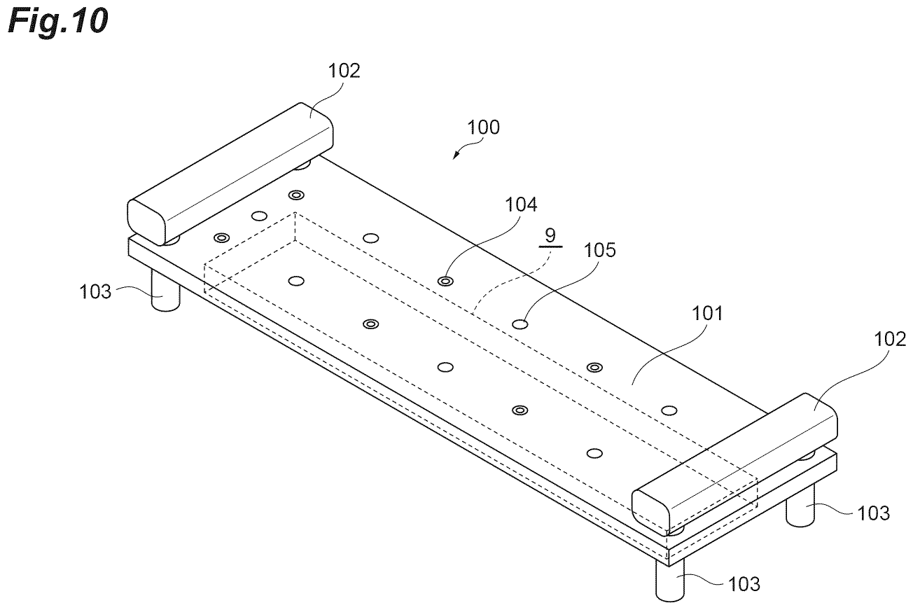

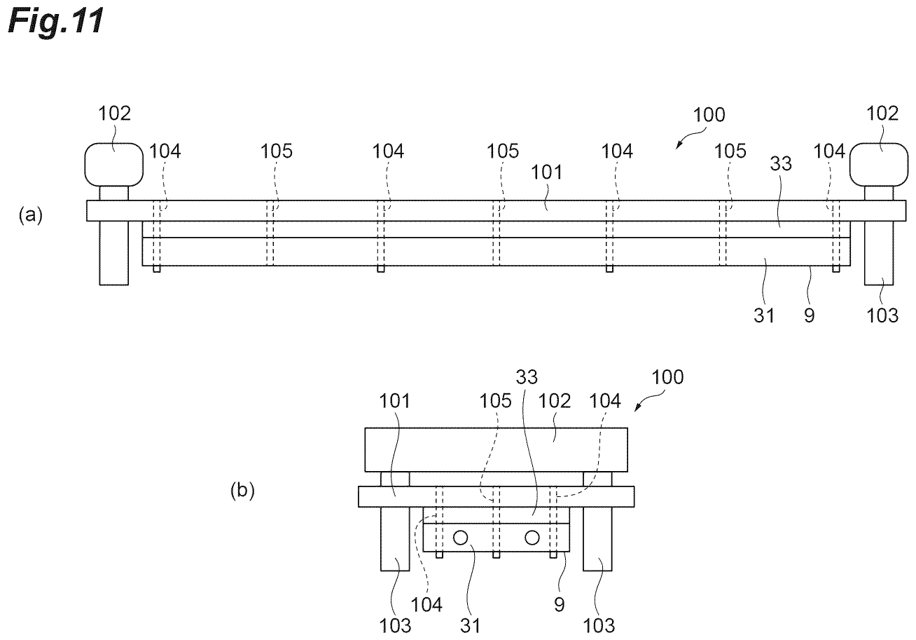

Subsequently, a jig and a procedure for attaching and detaching the output window unit 9 (or the output window unit 9C (hereinafter, the same)) to and from the vacuum container 3 will be described. FIG. 10 is a perspective view illustrating an attachment/detachment jig for the output window unit. FIG. 11 is a side view of the attachment/detachment jig illustrated in FIG. 10. (a) in FIG. 11 is a side view of the attachment/detachment jig (output window unit 9) when viewed in the transverse direction, and (b) in FIG. 11 is a side view of the attachment/detachment jig (output window unit 9) when viewed in the longitudinal direction.

As illustrated in FIGS. 10 and 11, an attachment/detachment jig 100 includes a protection cover 101, a pair of handles 102, and four temporary fastening mechanisms 103. The protection cover 101 has an elongated rectangular plate shape, and is made of a transparent material such that the output window unit 9 disposed on one surface side of the protection cover 101 is visible from the other surface side. Lengths of the protection cover 101 in a longitudinal direction and a transverse direction of the protection cover 101 are longer than lengths of the output window unit 9 in the longitudinal direction and the transverse direction, and the protection cover 101 is larger than the output window unit 9.

A plurality of through-holes 104 are formed in the protection cover 101. Fastening members such as bolts for fixing the output window unit 9 disposed on the one surface side of the protection cover 101 and the protection cover 101 to each other are inserted into the through-holes 104.

In the attachment/detachment jig 100, in a state where the output window unit 9 is disposed on the one surface side of the protection cover 101 such that the pressing member 33 faces a protection cover 101 side, the output window unit 9 is fixed to the protection cover 101 by the fastening members inserted into the through-holes 104 of the protection cover 101.

Accordingly, the opening portion 81 of the pressing member 33 which exposes the window foil 32 is closed by the protection cover 101, and inadvertent contact with the window foil 32 is suppressed.

In addition, a plurality of through-holes 105 are formed in the protection cover 101. Fastening members such as bolts for fastening the output window unit 9 and the vacuum container 3 (flange portion 3k) to each other are inserted into the through-holes 105. Therefore, in a state where the output window unit 9 is fixed to the attachment/detachment jig 100, the output window unit 9 can be fixed to the vacuum container 3 by the fastening members inserted into the through-holes 105. Incidentally, here, the through-holes 104 and the through-holes 105 are alternately arranged in a rectangular frame-shaped region along the outer shape of the output window unit 9.

The temporary fastening mechanisms 103 are provided on the one surface side of the protection cover 101 at four corners of the protection cover 101. The temporary fastening mechanisms 103 are abutted against receiving portions on the vacuum container 3 (flange portion 3k) side and locked, so that the attachment/detachment jig 100 and the output window unit 9 held by the attachment/detachment jig 100 can be temporarily fastened to the vacuum container 3. In addition, the temporary fastening of the attachment/detachment jig 100 to the vacuum container 3 can be released by releasing the locked state of the temporary fastening mechanisms 103.

The handles 102 are provided at both respective end portions of the protection cover 101 in the longitudinal direction on the other surface side of the protection cover 101. The handles 102 have the function of operating the locked state of the temporary fastening mechanisms 103. More specifically, for example, switches that are pressed down when the handles 102 are gripped are provided on surfaces on the protection cover 101 side of the handles 102. The temporary fastening mechanisms 103 are unlocked (for example, mechanically) by gripping the handles 102 to press down the switches, and the temporary fastening mechanisms 103 are locked by releasing the gripping of the handles 102 to release the pressing down of the switches.

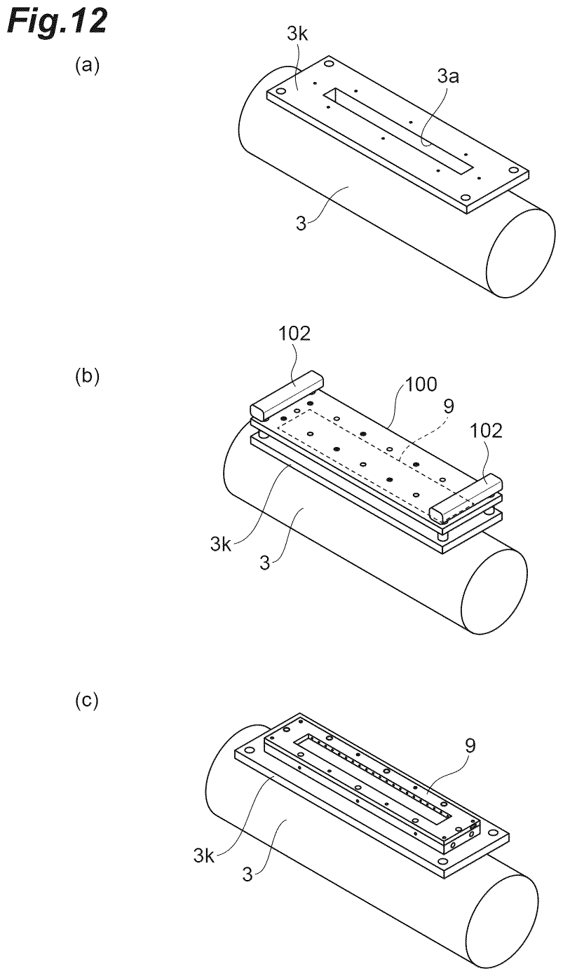

FIG. 12 is a perspective view for describing a procedure for attaching the output window unit to the vacuum container using the attachment/detachment jig illustrated in FIGS. 10 and 11. In (a) of FIG. 12, the output window unit 9 is not attached to the vacuum container 3, and the opening portion 3a of the flange portion 3k is opened. In contrast, as illustrated in (b) of FIG. 12, the output window unit 9 is held by the attachment/detachment jig 100, and at the time, a gas having positive pressure with respect to atmospheric pressure is sealed in a space (opening portion 81) between the protection cover 101 and the window foil 32 to prevent the window foil 32 from being lifted up.

Subsequently, the attachment/detachment jig 100 is conveyed onto the flange portion 3k with the handles 102 gripped. At this time, the temporary fastening mechanisms 103 are unlocked by gripping the handles 102. Subsequently, in this state, the temporary fastening mechanisms 103 are abutted against the receiving portions of the flange portion 3k, and the gripping of the handles 102 is released (the handles 102 are released). Accordingly, the temporary fastening mechanisms 103 are locked, and the attachment/detachment jig 100 and the output window unit 9 are temporarily fixed to the flange portion 3k.

Subsequently, the output window unit 9 is fixed to the flange portion 3k via the protection cover 101 by inserting fastening members into the through-holes 105 of the protection cover 101. Thereafter, while evacuating the inside of the vacuum container 3, it is confirmed that vacuuming is performed without any leaks. Subsequently, the fixation between the attachment/detachment jig 100 and the output window unit 9 is released by removing the fastening members inserted into the through-holes 104. Thereafter, the handles 102 are gripped again to unlock the temporary fastening mechanisms 103, and the attachment/detachment jig 100 is removed from the flange portion 3k. Accordingly, as illustrated in (c) of FIG. 12, only the output window unit 9 remains on the vacuum container 3 side, and the attachment of the output window unit 9 is completed.

As described above, by using the attachment/detachment jig 100, the output window unit 9 can be attached to and detached from the vacuum container 3 while protecting the window foil 32 using the protection cover 101. In addition, the attachment/detachment jig 100 and the output window unit 9 can be temporarily fixed to the vacuum container 3 by gripping the handles 102 and releasing the gripping of the handles 102, and a separate operation for the temporary fixing is not required. Therefore, the output window unit 9 can be easily attached and detached regardless of the attachment direction of the output window unit 9.

In addition, by using the attachment/detachment jig 100, the opening portion 81 of the pressing member 33 of the output window unit 9 can also be closed by the protection cover 101, and positive pressure can also be applied to the outside of the window foil 32.

Subsequently, a cooling procedure for the electron beam irradiation device 1 which includes the cooling of the output window unit 9 described above will be described. FIG. 13 is a perspective view schematically illustrating a cooling portion of the electron beam irradiation device. As illustrated in FIG. 13, in the electron beam irradiation device 1, a vacuum pump 3p is connected to the exhaust port 3b for discharging air from inside the vacuum container 3. The vacuum pump 3p is provided with a cooling portion A1.

In addition, the high-voltage supply plug 7p is connected to the flange portion 7a that seals the opening portion 3c of the vacuum container 3. The high-voltage supply plug 7p is provided with a cooling portion A2. In addition, the flow path 61 of the output window unit 9 constitutes a cooling portion A3 of the output window unit 9. Further, a cooling portion A4 is provided in a region on the output window unit 9 side of the side surface 3s of the vacuum container 3. Each part is cooled by allowing a refrigerant, which is, for example, a liquid, to flow through the cooling portions A1 to A4. The cooling portions A1, A2, and A4 are, for example, cooling jackets.

By the way, the limit temperature/target temperature of each part of the electron beam irradiation device 1 decreases in order of the side surface 3s of the vacuum container 3, the output window unit 9, the high-voltage supply plug 7p, and the vacuum pump 3p, and it is desirable that the lower the limit temperature/target temperature is, the lower the temperature of the refrigerant used for cooling is. Therefore, the electron beam irradiation device 1 is configured such that a flow path of the cooling portion A1 of the vacuum pump 3p, a flow path of the cooling portion A2 of the high-voltage supply plug 7p, the flow path 61 of the cooling portion A3 of the output window unit 9, and a flow path of the cooling portion A4 of the side surface 3s of the vacuum container 3 are connected in series in order, and the refrigerant flows through the cooling portion A1, the cooling portion A2, the cooling portion A3, and the cooling portion A4 in order.

Accordingly, the lower the limit temperature/target temperature of a portion of the electron beam irradiation device 1 is, the lower the temperature of the refrigerant usable for cooling is. In addition, by connecting the flow paths of the cooling portion A1, the cooling portion A2, the cooling portion A3, and the cooling portion A4 in series, a pipe for the refrigerant is made short, so that handling is facilitated.

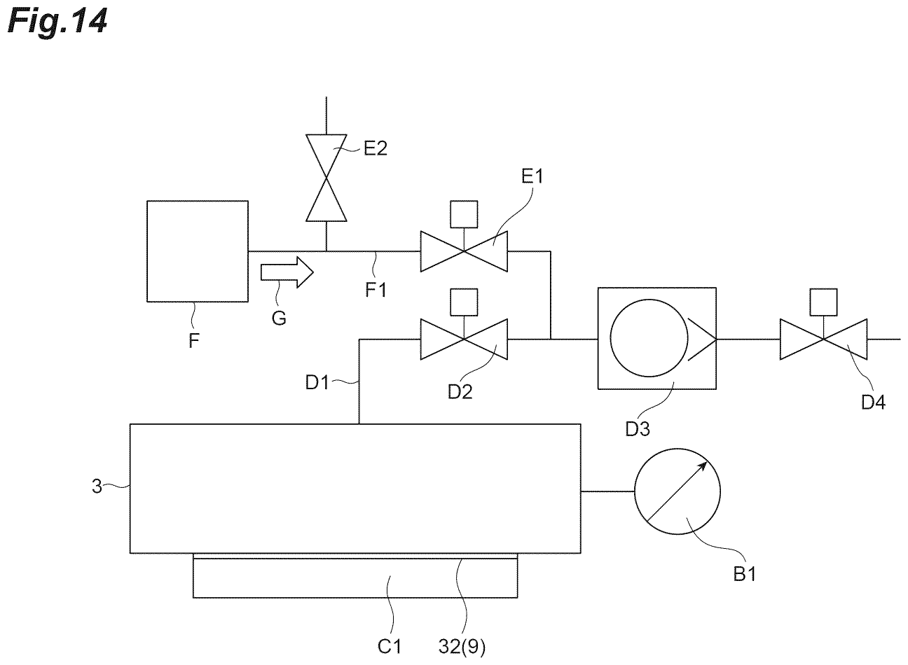

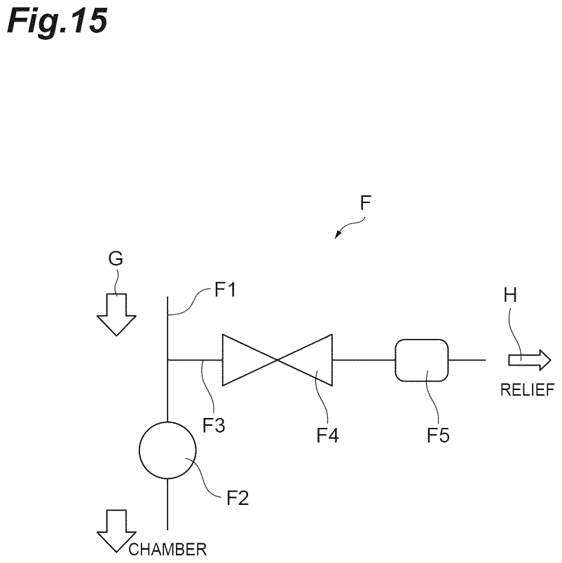

Subsequently, a configuration for adjusting the air pressure inside the vacuum container 3 will be described with reference to FIGS. 14 and 15. As illustrated in FIG. 14, an exhaust pipe D1 is connected to the vacuum container 3. A valve D2, a vacuum pump D3 (for example, the vacuum pump 3p described above), and a valve D4 are provided in the exhaust pipe D1 in order from the vacuum container 3 side. In addition, the vacuum container 3 is provided with a vacuum gauge B1. With this configuration, by opening the valves D2 and D4 and driving the vacuum pump D3, the exhausting (vacuuming) of the vacuum container 3 can be performed while measuring the pressure inside the vacuum container 3 using the vacuum gauge B1.

Meanwhile, a supply pipe F1 for supplying an inert gas into the vacuum container 3 is connected to the exhaust pipe D1 between the valve D2 and the vacuum pump D3. A leak valve E1 and a supply unit F are provided in the supply pipe F1 in order from the side of a connecting portion between the supply pipe F1 and the exhaust pipe D1. In addition, a relief pipe branches off from the supply pipe F1 between the leak valve E1 and the supply unit F, and a relief valve E2 is provided in the relief pipe.

As illustrated in FIGS. 14 and 15, the supply unit F can supply an inert gas G such as nitrogen into the vacuum container 3 via a pressure gauge F2, the leak valve E1, and the valve D2 by introducing the inert gas G into the supply pipe F1. At this time, the pressure of the inert gas G can be measured by the pressure gauge F2 or a flow meter F5 provided in a pipe F3 branched off from an upstream side of the pressure gauge F2 of the supply pipe F1. Accordingly, the air pressure inside the vacuum container 3 can be increased by the inert gas G while measuring the pressure inside the vacuum container 3. Incidentally, a relief valve F4 is provided in the pipe F3 between a branch portion from the supply pipe F1 and the flow meter F5. The relief valves E2 and F4 are provided with mechanisms for releasing gas when the pressure inside the vacuum container 3 reaches a certain level or higher.

Further, in the output window unit 9, a window foil positive pressure jig C1 is provided on the side of the window foil 32 opposite to the vacuum container 3 (the outside of the window foil 32), and positive pressure is applied to the outside of the window foil 32. With the above-described configuration, the relationship between the pressure outside the window foil 32 and the pressure inside the vacuum container 3 can be optionally adjusted.

By the way, generally, in an electron beam irradiation device, when work of replacing a consumable member such as an electron beam emission window or a filament (maintenance work) is performed, the work may be performed after the pressure inside a vacuum container returns to atmospheric pressure. As a method for returning the pressure inside the vacuum container to atmospheric pressure, supplying an inert gas into the vacuum container is considered. However, when the inert gas is supplied into the vacuum container, the pressure inside the vacuum container becomes positive pressure, so that a window foil is lifted up and wrinkles occur in the window foil when air inside the vacuum container is exhausted again, which is a risk.

In contrast, in the electron beam irradiation device 1, as described above, when the inert gas G is supplied into the vacuum container 3, the relationship between the pressure outside the window foil 32 and the pressure inside the vacuum container 3 can be adjusted. Specifically, in the electron beam irradiation device 1, the pressure of each part is adjusted such that the pressure outside the window foil 32>the pressure inside the vacuum container 3>the atmospheric pressure is established. As one example, the pressure outside the window foil 32 is approximately 0.05 MPa to 0.1 MPa, and the pressure inside the vacuum container 3 is approximately 0.001 MPa to b0.05 MPa (however, within a maximum allowable pressure of the vacuum pump D3). A pressure difference between the pressure outside the window foil 32 and the pressure inside the vacuum container 3 may be, for example, 0.01 MPa or more or 0.03 MPa or more. As described above, the occurrence of wrinkles in the window foil 32 during maintenance work of the electron beam irradiation device 1 is suppressed.

### REFERENCE SIGNS LIST

1: electron beam irradiation device, 3: vacuum container (housing), 9: output window unit, 31: support member, 32: window foil, 33: pressing member, 40: mesh portion, 41: through-hole, 50: frame portion, 60: fixing portion, 61: flow path (first flow path), 70: recess, 71: edge portion, 72: bottom surface portion, 81: opening portion, 82: flow path (second flow path), 83: communication hole, 85: cooling portion.

1. An output window unit provided in an electron beam irradiation device including an electron source and a housing accommodating the electron source, and configured to output an electron beam from the electron source to an outside of the housing, comprising:
a window foil configured to transmit the electron beam toward the outside of the housing; and
a support member fixed to the housing and configured to support the window foil,
wherein the support member includes a mesh portion facing the window foil and in which a plurality of through-holes through which the electron beam from the electron source passes toward a window foil side are formed, a frame portion having a solid shape and formed integrally with the mesh portion to surround the mesh portion when viewed in a first direction that is a direction in which the window foil and the mesh portion face each other, an outer portion located outside the mesh portion and the frame portion when viewed in the first direction, and formed integrally with the mesh portion and the frame portion, and a recess formed to be recessed along the first direction,
the outer portion includes a fixing portion used to fix the support member to the housing, and forms an edge portion of the recess, and
the mesh portion and the frame portion form a bottom surface portion of the recess, so that a thickness of the mesh portion and the frame portion in the first direction is thinner than a thickness of at least a portion forming the edge portion in the outer portion.

2. The output window unit according to claim 1,
wherein a corner portion forming a connecting portion between the bottom surface portion and the edge portion of the recess is chamfered.

3. The output window unit according to claim 1,
wherein a first flow path formed inside the fixing portion and configured to flow a first refrigerant.

4. The output window unit according to claim 1, further comprising:
a pressing member configured to press the window foil against the support member; and
a cooling portion configured to spray a second refrigerant, which is a gas, onto the window foil,
wherein an opening portion configured to expose at least a facing portion is formed in the pressing member, the facing portion being a part of the window foil and facing the mesh portion when viewed in the first direction, and
the cooling portion sprays the second refrigerant onto the facing portion of the window foil through the opening portion of the pressing member.

5. The output window unit according to claim 4,
wherein the cooling portion includes a second flow path formed inside the pressing member and configured to flow the second refrigerant, and a communication hole allowing communication between the second flow path and an inside of the opening portion, and sprays the second refrigerant, which has flowed through the second flow path, onto the facing portion by leading out the second refrigerant into the inside of the opening portion through the communication hole.

6. The output window unit according to claim 1,
wherein the recess is open toward a housing side, and
the window foil is disposed on a front surface of the support member opposite to an opening of the recess.

7. The output window unit according to claim 1,
wherein the recess is open toward a side opposite to the housing, and
the window foil is disposed inside the recess.
